(19) United States
(12) Patent Application Publication
(10) Pub. No.: US 2019/0013240 A1
(43) Pub. Date: Jan. 10, 2019

(54) INTERCONNECTS FORMED WITH STRUCTURALLY-MODIFIED CAPS

(71) Applicant: GLOBALFOUNDRIES Inc., Grand Cayman (KY)

(72) Inventors: Nicholas V. LiCausi, Watervliet, NY (US); Xunyuan Zhang, Troy, NY (US); Errol Todd Ryan, Clifton Park, NY (US)

(21) Appl. No.: 15/643,843

(22) Filed: Jul. 7, 2017

(51) Int. Cl. H01L 21/768; H01L 21/3215; H01L 21/3213; H01L 23/532; H01L 23/522

(52) U.S. Cl. CPC H01L 21/76886; H01L 21/76802; H01L 21/76877; H01L 23/5226; H01L 21/32133; H01L 23/53228; H01L 21/3215

(57) ABSTRACT

Interconnects and methods for forming interconnects. An interconnect opening is formed in a dielectric layer, and a conductive layer is formed in the interconnect opening. A modified section is formed in the conductive layer near a top surface of the conductive layer. After the modified section is formed, the modified section of the conductive layer is recessed with an etching process that at least partially removes the modified section. The modified section may have a composition that includes niobium.

### BACKGROUND

The present invention relates to integrated circuits and semiconductor device fabrication and, more specifically, to interconnects and methods for forming interconnects.

An interconnect structure may be used to electrically connect device structures fabricated by front-end-of-line (FEOL) processing. A back-end-of-line (BEOL) portion of the interconnect structure may include metallization formed using a damascene process in which via openings and trenches etching in a dielectric layer are filled with metal to create features of a metallization level.

Copper is a common material used in the metallization of the BEOL portion of the interconnect structure. With scaling to smaller feature sizes (e.g., 5 nm and smaller nodes), the behavior of copper hinders the formation BEOL features, such as fully aligned vias (FAVs), that are characterized by high aspect ratios of depth to width. After planarization, the top surfaces of BEOL features are recessed prior to the formation of a cap. The etching process that provides the recessing may exhibit a dependence in etch rate upon grain structure. The result is that the top surface, which is initially planar after polishing, is no longer planar due to roughness resulting from the grain-structure dependent etch rate.

Improved interconnects and methods for forming interconnects are needed.

### SUMMARY

According to an embodiment of the invention, a method includes forming an interconnect opening in a dielectric layer, forming a conductive layer in the interconnect opening, and forming a modified section in the conductive layer near a top surface of the conductive layer. After the modified section is formed, the modified section of the conductive layer is recessed with an etching process that at least partially removes the modified section. The modified section may have a composition that includes niobium.

According to an embodiment of the invention, a structure includes a dielectric layer with an interconnect opening and a conductive layer in the interconnect opening. The conductive layer includes a top surface, a bottom surface, and a modified section near the top surface. The modified section may have a composition that includes niobium.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-4 are cross-sectional views of a structure at successive fabrication stages of a processing method in accordance with embodiments of the invention.

FIG. 5 is a cross-sectional view of a structure at a fabrication stage subsequent to FIG. 3 of a processing method in accordance with alternative embodiments of the invention.

FIG. 6 is a cross-sectional view of a structure at a fabrication stage subsequent to FIG. 2 of a processing method in accordance with alternative embodiments of the invention.

### DETAILED DESCRIPTION

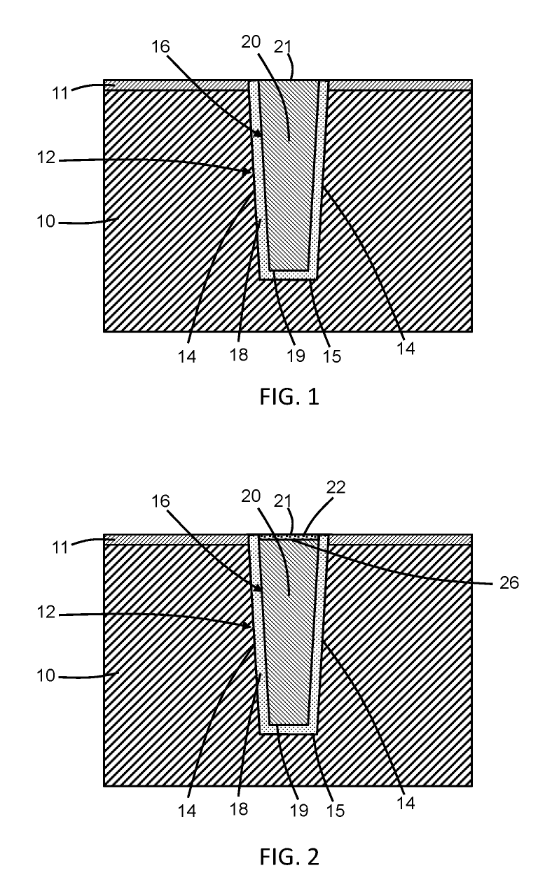

With reference to FIG. 1 and in accordance with an embodiment of the invention, a dielectric layer 10 may be processed by middle-of-line (MOL) processing or by back-end-of-line (BEOL) to form a metallization level of an interconnect structure. The dielectric layer 10 may be composed of an electrical insulator, such as silicon dioxide (SiO₂) or another suitable dielectric material, such as a low-k dielectric material or an ultra-low-k (ULK) dielectric material having a dielectric constant that is less than the dielectric constant of silicon dioxide. A dielectric layer 11 may be formed on the top surface of the dielectric layer 10.

Interconnect openings, of which interconnect opening 12 is representative, may be formed by photolithography and etching at selected locations distributed across the surface area of dielectric layers 10, 11. Specifically, a photoresist layer may be applied, exposed to a pattern of radiation projected through a photomask, and developed to form a corresponding pattern of openings situated at the intended locations for the interconnect openings The patterned photoresist layer is used as an etch mask for a dry etching process, such as a reactive-ion etching (RIE), that removes portions of the dielectric layers 10, 11 to form the interconnect openings. The etching process may be conducted in a single etching step or multiple etching steps with different etch chemistries and with the use of additional hard mask layers.

The interconnect opening 12 may be a contact opening or a trench defined in the dielectric layers 10, 11 and may have an aspect ratio of height-to-width that is characteristic of a contact opening or a trench. The interconnect opening 12 has one or more sidewalls 14 that penetrate from a top surface of the dielectric layer 11 to a surface at the bottom 15 of the interconnect opening 12. The sidewalls 14 are bounded by the dielectric material of the dielectric layers 10, 11 and primarily by the dielectric material of the dielectric layer 10), and the bottom 15 may also be bounded by the dielectric material of the dielectric layer 10. The interconnect opening 12 may penetrate to a given depth into the dielectric layer 10 that is less than the thickness of dielectric layer 10 or may penetrate completely through the thickness of dielectric layer 10. The interconnect opening 12 may land at its bottom 15 on an underlying conductive feature (not shown) as part of a process to establish a vertical interconnection.

A barrier/liner layer 18 of a given thickness is arranged on the sidewalls 14 and at the bottom 15 of the interconnect opening 12. The barrier/liner layer 18 may be comprised of cobalt (Co), titanium (Ti), titanium nitride (TiN), tantalum (Ta), tantalum nitride (TaN), ruthenium (Ru), or a multilayer combination of these materials (e.g., a Ta/TaN bilayer) deposited by physical vapor deposition (PVD) with, for example, a sputter-assisted process, chemical vapor deposition (CVD) or atomic layer deposition (ALD). The barrier/liner layer 18 conforms to the shape of the interconnect opening 12 such that the dielectric layers 10, 11 bordering the sidewalls 14 of the interconnect opening 12 and the bottom surface 15 of the interconnect opening 12 are completely covered by a uniform given thickness.

An interconnect feature 16 is arranged inside the interconnect opening 12. The interconnect feature 16 includes a conductive layer 20 of a given thickness that is formed inside the interconnect opening 12 in contact with the barrier/liner layer 18. The conductive layer 20 may be deposited by electroless deposition, which may require the prior deposition of a conformal seed layer by PVD, or may be formed by a reflow process. The conductive layer 20 may be composed of copper (Cu) or a copper-manganese (Cu—Mn) alloy, and may be polycrystalline and characterized by material properties, such as an average grain size.

The materials of the barrier/liner layer 18 and the conductive layer 20 and/or its seed layer formed on the field area on the top surface of the dielectric layers 10, 11 may be removed with a chemical mechanical polishing (CMP) process. Material removal during the CMP process combines abrasion and an etching effect that polishes the targeted material and may be conducted with a commercial tool using polishing pads and slurries selected to polish the targeted material(s). The conductive layer 20 of the interconnect feature 16 inside the interconnect opening 12 is planarized relative to the top surface of the dielectric layer 11 by the CMP process. The top surface 21 of the conductive layer 20 may be planar and flat, and may be coplanar with the top surface of the dielectric layer 11. The conductive layer 20 has a bottom surface 19 that is located adjacent to the bottom 15 of the interconnect opening 12. The barrier/liner layer 18 is disposed between the conductive layer 20 and the sidewalls 14 and bottom 15 of the interconnect opening 12.

With reference to FIG. 2 in which like reference numerals refer to like features in FIG. 1 and at a subsequent fabrication stage, a modified section 22 is formed in the conductive layer 20 adjacent to its top surface 21 and vertically between its top surface 21 and its bottom surface 19. A lower section of the conductive layer 20 is not modified and retains its original composition and crystalline state. The modified section 22 and the non-modified section of the conductive layer 20 converge and join along an interface 26. The non-modified section of the conductive layer 20 is located vertically between the interface 26 and the bottom surface 19 of the conductive layer 20, and the modified section 22 of the conductive layer 20 is located vertically between the interface 26 and the top surface 21 of the conductive layer 20. In an embodiment, the modified section 22 intersects the top surface 21. In an alternative embodiment, the modified section 22 may be spaced from the top surface 21 by a small distance. The top surface 21 of the conductive layer 20 may retain its planarity following the formation of the modified section 22.

An element is introduced into the conductive layer 20 so as to form the modified section 22. The introduced element may be an element that is initially absent from the as-formed conductive layer 20. In an embodiment, the modified section 22 may be formed by implanting the conductive layer 20 with energetic ions that are introduced through the top surface 21 of the conductive layer 20 and that stop in the conductive layer 20 adjacent to the top surface 21. The trajectories of the ions penetrate into the conductive layer 20 with a depth profile parameterized by a projected range and a range straggle. The ions may be generated from a suitable source gas and implanted with selected implantation conditions using an ion implantation tool. The implantation conditions (e.g., ion species, dose, kinetic energy) may be selected to tune the characteristics (e.g., depth profile and physical properties) of the modified section 22. In embodiments, the element delivered by the ions may include, but is not limited to, niobium (Nb), aluminum (Al), cobalt (Co), ruthenium (Ru), or hydrogen (H).

The ions may deliver an element that is capable of combining with the conductor of the conductive layer 20 to dope the modified section 22 and/or to form an alloy in the modified section 22. The crystal structure of the modified section 22, in comparison with the polycrystalline structure of the non-modified section, may be amorphous and free of detectable grains. Alternatively, the crystal structure of the modified section 22, in comparison with the polycrystalline structure of the non-modified section, may be a fine-grained structure characterized by grains with an average grain size that is significantly smaller than the average grain size of the grains in the non-modified section of the conductive layer 20. The modified section 22 may be conductive following the implantation.

In an embodiment, the element delivered by the ions may be niobium (Nb). For example, niobium ions may be implanted at an energy in a range of 5 keV to 25 keV and with a dose of 1×10¹⁵ cm⁻² to 1×10¹⁶ cm⁻². The modified section 22 may be an alloy of niobium and copper, as well as any alloying elements (e.g., manganese) present in the conductive layer 20 before the performance of the implantation. The thickness of the ion-implanted modified section 22 can range from two (2) nm to fifteen (15) nm.

In an alternative embodiment, the modified section 22 may be formed by in a different manner. For example, a plasma containing the modifying element (e.g., Nb) can be used to selectively incorporate the element into the conductive layer 20 at the top surface 21 of the conductive layer 20. The plasma may include, for example, the species NbH₄ that is generated from an organic precursor such as Tris(diethylamido)(tert-butylimido)niobium(V) (C₁₆H₃₉N₄Nb) or Bis(cyclopentadienyl)niobium(IV) dichloride 95% (C₁₀H₁₀C₁₂Nb).

With reference to FIG. 3 in which like reference numerals refer to like features in FIG. 2 and at a subsequent fabrication stage, a thermal process may be used to provide a drive in that extends the depth of the modified section 22 by diffusion of the element introduced by the ion implantation. The thermal process, which is optional, may be a thermal anneal in a furnace, a laser anneal, a spike anneal or a soak anneal performed by rapid thermal annealing, or any combination thereof. The dielectric layer 11 may be stripped using a wet chemical solution containing hydrofluoric (HF) acid or another wet chemical etchant, or may be removed with a dry etching process using a plasma formed from, for example, a combination of carbon tetrafluoride (CF₄) and ozone (O₂). In an alternative embodiment, the dielectric layer 11 may not be stripped, and may remain as a hardmask in the completed interconnect structure instead of being removed.

With reference to FIG. 4 in which like reference numerals refer to like features in FIG. 3 and at a subsequent fabrication stage, the barrier/liner layer 18 and modified section 22 are recessed relative to the top surface of the dielectric layer 10 using an etching process. The etching process may rely on one or more etch chemistries that remove the materials of the barrier/liner layer 18 and modified section 22 selective to the material of the dielectric layer 10. As used herein, the term “selective” in reference to a material removal process (e.g., etching) denotes that, with an appropriate etchant choice, the material removal rate (i.e., etch rate) for the targeted material is greater than the removal rate for at least another material exposed to the material removal process. The etching process retains the planarity of the top surface 21 of the conductive layer 20 due to the presence of the modified section 22, and the modified section 22 is only partially removed. The interconnect feature 16 is a hybrid feature that includes the conductive layer 20 and a portion of the modified section 22.

A dielectric cap 28 composed of a dielectric material, such as silicon nitride (Si₃N₄), with etch selectivity to the dielectric material of the dielectric layer 10 may be deposited to cover the top surface 21 of the conductive layer 20 and the top surface of the dielectric layer 11. The remainder of the modified section 22 operates as a metal cap that is arranged between the dielectric cap 28 and the non-modified section of the conductive layer 20 that is located between the modified section 22 and the bottom 15 of the interconnect opening 12. In this regard, the conductive layer 20 may not require the formation of an additional metal cap (e.g., a metal cap composed of cobalt).

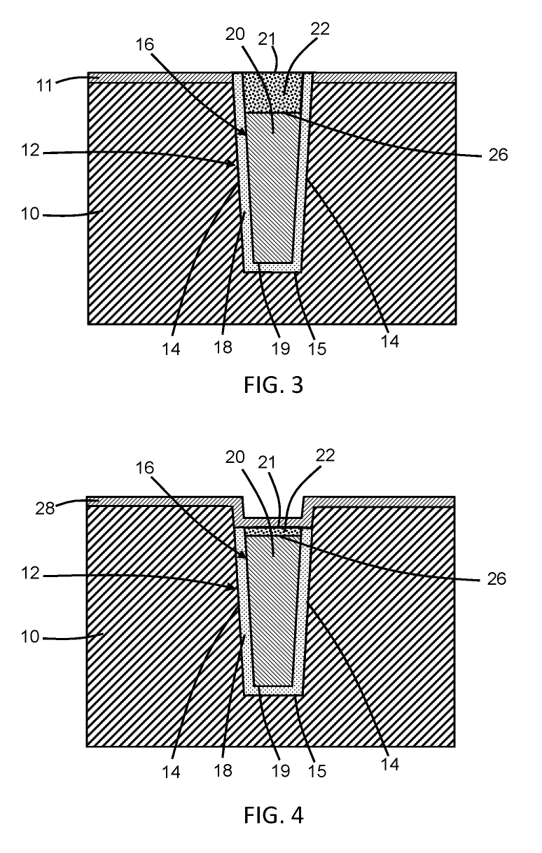

In an alternative embodiment shown in FIG. 5, the modified section 22 may be completely removed by extending the depth of the etching process past the interface 26 such that the conductive layer 20 is revealed and recessed after the modified section 22 is removed. A metal cap 30 comprised of, for example, cobalt (Co) may be applied and the process may continue with the formation of the dielectric cap 28. The complete removal of the modified section 22 may operate to lower the electrical resistance of the conductive layer 20 and interconnect feature 16 if the conductor in the modified section 22 of the conductive layer 20 has a higher electrical resistivity than the conductor in the non-modified section of the conductive layer 20.

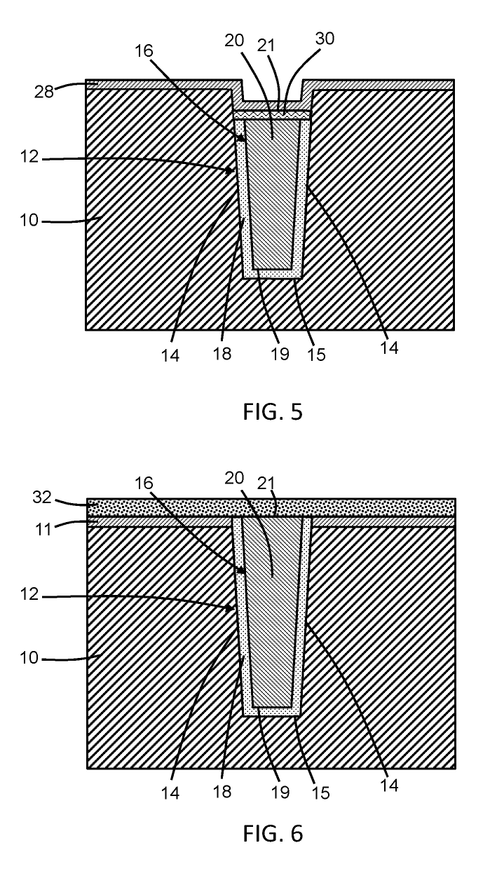

With reference to FIG. 6 in which like reference numerals refer to like features in FIG. 2 and at a subsequent fabrication stage in accordance with alternative embodiments, the modified section 22 may be formed in a different manner that involves the deposition of a layer 32 containing the element (e.g., Nb) that is used to form the modified section 22. The layer 32 may be deposited on the conductive layer 20 using chemical vapor deposition (CVD) or physical vapor deposition (PVD). The layer 32 may be in direct contact with the top surface 21 of the conductive layer 20. A thermal process, which is described in the context of FIG. 3, may be used to provide a drive in that causes the modifying element to be transported from the layer 32 into the conductive layer 20, which generates the alloy forming the modified section 22. The modified section 22 may be an alloy that contains as much as 40 percent to 90 percent of the modifying element that is transported from the layer 32 to the conductive layer 20. The layer 32 may be stripped with an etching process following the formation of the modified section 22, followed by the actions described in the context of FIG. 3 and FIG. 4 to form the interconnect feature 16 of either FIG. 4 or FIG. 5.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction perpendicular to the horizontal, as just defined. The term “lateral” refers to a direction within the horizontal plane. Terms such as “above” and “below” are used to indicate positioning of elements or structures relative to each other as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method comprising:
forming an interconnect opening in a first dielectric layer;
forming a conductive layer in the interconnect opening;
forming a modified section in the conductive layer near a top surface of the conductive layer; and
after forming the modified section, recessing the modified section of the conductive layer within the interconnect opening relative to a top surface of the first dielectric layer with an etching process that at least partially removes the modified section.

2. The method of claim 1 wherein forming the modified section comprises:
implanting ions through the top surface of the conductive layer to deliver an element to the conductive layer so as to form the modified section.

3. The method of claim 2 wherein the element delivered by the ions to the modified section is niobium.

4. The method of claim 2 further comprising:
after forming the modified section, annealing the conductive layer to transport the element to a greater depth in the conductive layer and to deepen the modified section within the interconnect opening.

5. The method of claim 1 wherein forming the modified section comprises:
introducing niobium into the conductive layer to form the modified section.

6. The method of claim 1 wherein forming the modified section comprises:
depositing a layer on the top surface of the conductive layer; and
annealing to cause an element from the layer to be transported from the layer to the conductive layer so as to form the modified section.

7. The method of claim 6 wherein forming the modified section further comprises:
after forming the modified section, removing the layer from the top surface of the conductive layer.

8. The method of claim 1 wherein forming the modified section comprises:
exposing the top surface of the conductive layer to a plasma generated from an organic precursor containing an element.

9. The method of claim 8 wherein the element combines with a conductor of the conductive layer to form the modified section, and further comprising:
after the forming modified section, annealing the conductive layer to transport the element to a greater depth into the conductive layer and to deepen the modified section within the interconnect opening.

10. The method of claim 1 wherein recessing the modified section of the conductive layer with the etching process that at least partially removes the modified section comprises:
completely removing the modified section with the etching process.

11. The method of claim 10 further comprising:
recessing the conductive layer with the etching process.

12. The method of claim 1 wherein recessing the modified section of the conductive layer with the etching process that at least partially removes the modified section comprises:
partially removing the modified section with the etching process.

13. The method of claim 1 wherein the conductive layer is comprised of copper, and the modified section is an alloy including copper and niobium.

14. The method of claim 1 wherein the modified section has an amorphous structure that is free of detectable grains.

15. The method of claim 1 wherein the conductive layer includes a non-modified section, the modified section is located between the non-modified section and the top surface of the conductive layer, the non-modified section has a first structure with a first grain size, and the modified section has a second structure with a second grain size that is less than the first grain size.

16. A structure comprising:
a dielectric layer including an interconnect opening and a top surface; and
a conductive layer in the interconnect opening, the conductive layer including a top surface, a bottom surface, and a modified section near the top surface,
wherein the modified section of the conductive layer is recessed within the interconnect opening relative to the top surface of the first dielectric layer.

17. The structure of claim 16 wherein the conductive layer is comprised of copper, and the modified section is an alloy including copper and niobium.

18. The structure of claim 16 wherein the modified section has an amorphous structure that is free of detectable grains.

19. The structure of claim 16 wherein the conductive layer includes a non-modified section between the modified section and the bottom surface, the non-modified section has a first structure with a first grain size, and the modified section has a second structure with a second grain size that is less than the first grain size.

20. (canceled)

21. The method of claim 1 wherein the modified section comprises a first material, the first dielectric layer comprises a second material, and the etching process has an etch chemistry that removes the first material of the modified section selective to the second material of the first dielectric layer.
